(19) United States
(12) Patent Application Publication
(10) Pub. No.: US 2012/0063125 A1
(43) Pub. Date: Mar. 15, 2012

(54) DISPLAY CASE LIGHTING

(75) Inventors: Bruce Quaal, Ventura, CA (US); Brandon Brooks, Ventura, CA (US)

(73) Assignee: The Sloan Company, Inc. dba SloanLED

(21) Appl. No.: 13/049,766

(22) Filed: Mar. 16, 2011

Related U.S. Application Data
(60) Provisional application No. 61/314,935, filed on Mar. 17, 2010.

(51) Int. Cl. A47F 11/10; H05K 13/00; F21V 29/00; F21V 13/04; F21V 7/06

(52) U.S. Cl. 362/125; 362/243; 362/247; 29/592.1

(57) ABSTRACT

The present embodiments provide channel letter lighting devices and/or systems. A lighting unit, comprising: a housing; a printed circuit board (PCB) mounted within the housing and having a plurality light emitting elements on the PCB which emit light when an electrical signal is applied to the light emitters; and a plurality of reflectors, each of which comprised of an at least one partial parabola which reflects light substantially away from the housing, the plurality of reflectors over the PCB and the light emitters such that each of the light emitters is surrounded by at least one of the plurality of reflectors.

This application claims the benefit of provisional application Ser. No. 61/314,935 to Brooks et al., which was filed on Mar. 17, 2010. The contents of 61/314,935 are incorporated entirely herein by reference.

### BACKGROUND OF THE INVENTION

1. Field of the Invention

This invention relates to refrigerated display case lighting and more particularly to LED based refrigerated display case lighting.

2. Description of the Related Art

Display units, such as shelving units, refrigeration units, and freezer units, are commonly used in retail applications to display merchandise. The display units may be arranged into banks of wall displays so that the consumers may walk through aisles between the display units and readily view the merchandise contained in the display units. The display units may include vertical supports and doors, allowing consumers to see the merchandise contained in the display units without opening the display units and allowing consumers access to the merchandise by simply opening one of the doors.

To enhance the visibility of the merchandise in the display units, lighting may be incorporated therein. One way lighting has been incorporated into display units is by placing fluorescent lamps or other light sources horizontally within the display units, such as along horizontal supports. Another way lighting has been incorporated into display units is by placing fluorescent lamps or other light sources vertically within the display units, such as along vertical supports and door frames.

Typically, a fluorescent tube is used to illuminate products disposed in the display case. Fluorescent tubes do not have nearly as long a lifetime as a typical light emitting diode. Also, heat produced by fluorescent lights inside a refrigerator or freezer place an additional load on refrigeration systems. Furthermore, for refrigerated display cases, initiating the required arc to illuminate a fluorescent tube is difficult in a refrigerated compartment. These approaches do not always provide even lighting across the merchandise in the front of the display units. Providing sufficient lighting within the display units requires the consumption of significant energy. For example, a standard fluorescent lamp 60 inches in length consumes as much as 60 to 70 watts.

Alternative light sources have also been used, including light emitting diodes. However, many of these designs produce insignificant energy savings, non-uniform lighting, secondary spotting or “glare” effects, and unreasonable costs of manufacturing such light sources.

Therefore, it is desired to achieve uniform lighting of merchandise across the display units with a light source that consumes considerably less energy and is economical to manufacture.

### SUMMARY OF THE INVENTION

The present embodiments advantageously address the needs above as well as other needs by providing display case lighting devices, systems and methods of manufacturing same. Some embodiments provide a lighting unit. This lighting unit comprises a housing. A printed circuit board (PCB) is mounted within the housing and has a plurality of light emitting elements on the PCB which emit light when an electrical signal is applied to the light emitters. The lighting unit also comprises a plurality of reflectors, each of which comprised of an at least one partial parabola which reflects light substantially away from the housing. The plurality of reflectors over the PCB and the light emitters such that each of the light emitters is surrounded by at least one of the plurality of reflectors.

Other embodiments provide a lighting system, comprising: a plurality of electrically connected lighting units, comprising conductors to provide an electrical signal to each of the units. Each of the units comprises a housing and a printed circuit board (PCB) mounted within the housing. The PCB has a plurality of light emitting elements on the PCB which emit light when an electrical signal is applied to the light emitters. The units further comprise an at least one reflector over the PCB and the light emitters such that each of the light emitters is surrounded by an at least one partial parabola formed by the reflector, the at least one partial parabola reflecting light substantially away from the housing.

Some further embodiments provide display case lighting systems. These embodiments can comprise a plurality of electrically connected lighting units, comprising conductors to provide an electrical signal to each of the units. Each of the units comprises a housing and a printed circuit board (PCB) mounted within the housing. The PCB has a plurality of light emitting elements on the PCB which emit light when an electrical signal is applied to the light emitters. The units further comprise an at least one reflector over the PCB and the light emitters such that each of the light emitters is surrounded by an at least one partial parabola formed by the reflector. These partial parabola reflect light substantially away from the housing. The units also comprise a mounting mechanism for mounting the lighting units within a display case.

Some further embodiments provide methods for illuminating display cases. These embodiments can comprise providing a housing. Next, mounting a printed circuit board (PCB) within the housing and having a plurality of light emitting elements on the PCB which emit light when an electrical signal is applied to the light emitters. Further, providing an at least one reflector over the PCB and the light emitters such that each of the light emitters is surrounded by an at least one partial parabola formed by the reflector, and the at least one partial parabola is capable of reflecting light substantially away from the housing. Also, mounting the lighting units within a display case. Furthermore, redirecting light emitted from the light emitters with the at least one reflector such that the at least one partial parabola create evenly dispersed light in the display case and emitted light from each of the light emitters partially overlaps the emitted light of at least one other light emitter.

A better understanding of the features and advantages of the present embodiments will be obtained by reference to the following detailed description of the invention and accompanying drawings which set forth illustrative embodiments in which the principles of the invention are utilized.

### BRIEF DESCRIPTION OF THE DRAWINGS

FIG. 1 is a perspective view of a refrigeration system which contains one embodiment of a LED lighting unit system according to the present invention;

FIG. 2 is a view from the inside of the refrigeration system of FIG. 1 which contains one embodiment of a LED lighting unit system according to the present invention;

FIG. 3 is a top view from the inside of the refrigeration system of FIG. 1 which contains one embodiment of a LED lighting unit system according to the present invention;

FIG. 4 is a top view of a portion of one embodiment of an end lighting unit according to the present invention;

FIG. 5a is a perspective view of a portion of one embodiment of a center lighting unit according to the present invention;

FIG. 5b is a top view of a portion of one embodiment of a center lighting unit according to the present invention;

FIG. 6 is a perspective view of an embodiment of a reflector according to the present invention;

FIG. 7 is a perspective view of another embodiment of a reflector according to the present invention;

FIG. 8a is a plan view of one embodiment of an end cap for an end lighting unit according to the present invention;

FIG. 8b is a plan view of one embodiment of an end cap for a center lighting unit according to the present invention;

FIG. 9a is a perspective view of one embodiment of a clip to be used on a lighting unit according to the present invention;

FIG. 9b is a perspective view of another embodiment of a clip to be used on a lighting unit according to the present invention;

FIG. 10a is an exploded view of one embodiment of an end lighting unit according to the present invention;

FIG. 10b is an exploded view of one embodiment of a center lighting unit according to the present invention;

FIG. 11a is a top view of one embodiment of a lighting unit according to the present invention;

FIG. 11b is a top view of another embodiment of a lighting unit according to the present invention;

FIG. 11c is a side view of one embodiment of a lighting unit according to the present invention;

FIG. 11d is a bottom view of one embodiment of a lighting unit according to the present invention;

FIG. 12 is a top view of one embodiment of a reflector according to the present invention;

FIG. 13 is a graph indicating predicted illumination levels at a 3⅝″ merchandise level achieved by the use of one embodiment according to the present invention;

FIG. 14 is a graph indicating predicted illumination levels at a 6″ merchandise level achieved by the use of one embodiment according to the present invention;

FIG. 15 is a graph indicating predicted illumination levels at a 10″ merchandise level achieved by the use of one embodiment according to the present invention.

### DETAILED DESCRIPTION OF THE INVENTION

The present invention relates to a lighting system that can be used in applications such as display case lighting and refrigeration unit lighting. Systems according to embodiments of the present invention provide lighting units that are placed within display units to uniformly illuminate items therein.

The present invention is described herein with reference to certain embodiments but it is understood that the invention can be embodied in many different forms and should not be construed as limited to the embodiments set forth herein. In particular, the invention is described with reference to certain embodiments where the length between adjacent lighting units or lighting unit sections can be increased, but in other embodiments the length of the units can be decreased. In other embodiments, the number of lighting units or elements per unit may be increased or decreased impacting the density of lighting units and/or light emitter. Further, many different mechanism and arrangements can be used to allow for the output, guidance, or reflection of light from the lighting units or light sources to be adjusted along the length of the lighting units. In addition the lighting units may be constructed using a variety of materials. The present invention can also be used with different types of lighting units used in different applications beyond display case lighting, and although the present invention is described herein with reference to light emitting diodes (LED or LEDs) other light sources can be used.

It is also understood that when an element such as a layer, region or substrate is referred to as being “on” another element, it can be directly on the other element or intervening elements may also be present. Furthermore, relative terms such as “inner”, “outer”, “upper”, “above”, “lower”, “beneath”, and “below”, and similar terms, may be used herein to describe a relationship of one item or another region. It is understood that these terms are intended to encompass different orientations of the device in addition to the orientation depicted in the figures.

Although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to illustrations that are schematic illustrations of embodiments of the invention. As such, the actual thickness of the layers and features can be different, and variations from the shapes of the illustrations as a result, for example, of manufacturing techniques and/or tolerances are expected. Embodiments of the invention should not be construed as limited to the particular shapes of the regions illustrated herein but are to include deviations in shapes that result, for example, from manufacturing. A region illustrated or described as square or rectangular will typically have rounded or curved features due to normal manufacturing tolerances. Thus, the regions illustrated in the figures are schematic in nature and their shapes are not intended to illustrate the precise shape of a feature of a device and are not intended to limit the scope of the invention.

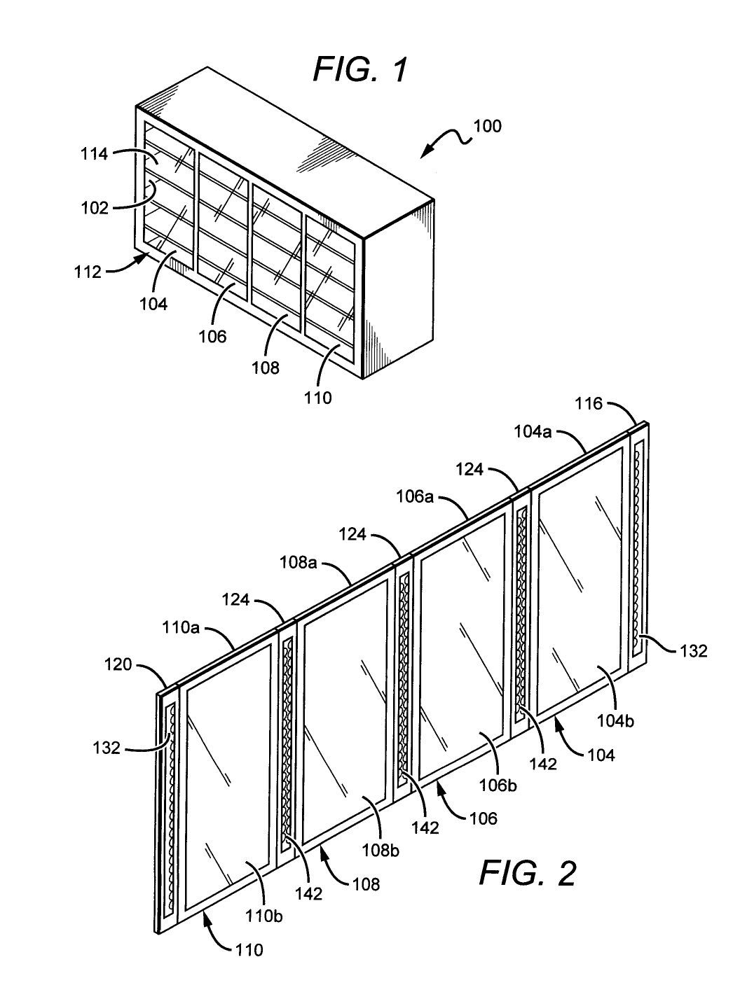

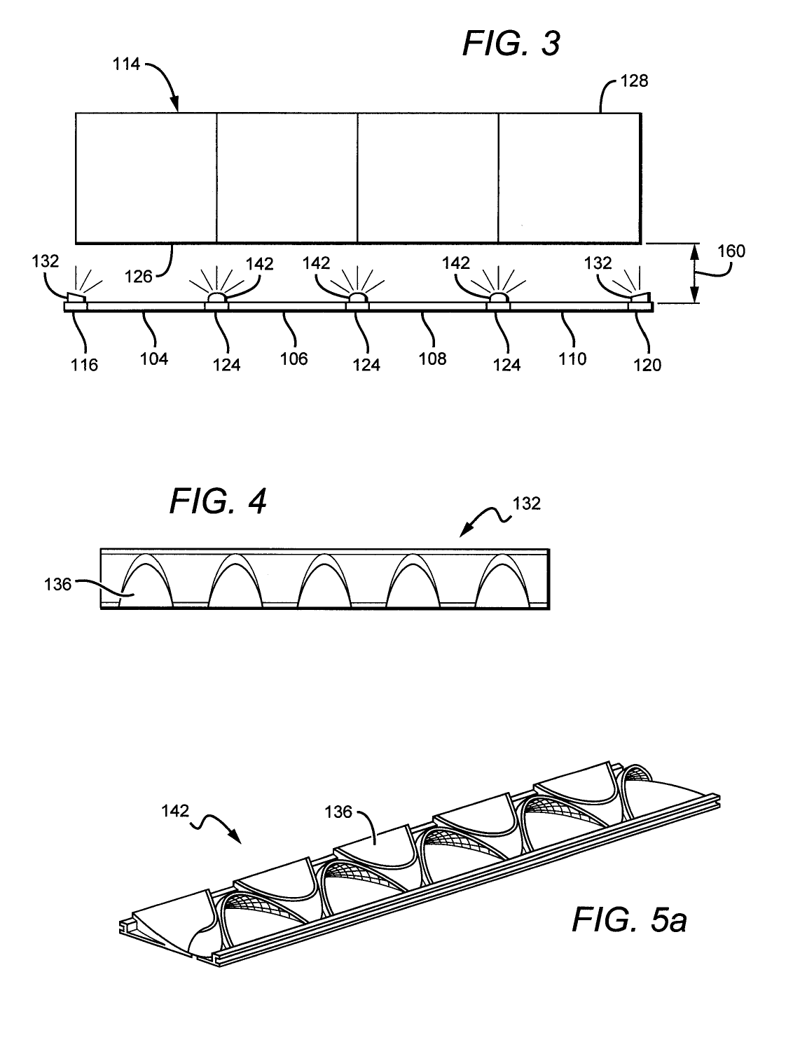

With reference to FIGS. 1 and 3, an exemplary refrigeration unit 100 is shown. The refrigeration unit 100 is preferably enclosed on all sides to define a cavity 102 and includes doors 104, 106, 108, 110 proximate to the front 112 of the refrigeration unit 100 which may be opened for access to merchandise displayed within the cavity 102 on horizontal supports such as shelves 114. The doors 104, 106, 108, 110 preferably include frames 104a, 106a, 108a, 110a with glass panels 104b, 106b, 108b, 110b, or panels made of any suitable translucent material so that the merchandise on the shelves 114 may be viewed through the doors 104, 106, 108, 110. The amount of space 160 between the doors 104, 106, 108, 110 and the front of the shelves 114 traditionally varies from 3 inches to 6 inches, but can be other distances as well. The front 112 of the refrigeration unit 100 includes a left vertical support 116, a right vertical support 120, and middle vertical supports 124 or mullions 124. The frame 104a is operatively connected to the left vertical support 116 and the middle vertical support or mullion 124 and the remaining frames and mullions are connected similarly.

Supports and mullions 116, 120, 124 are inside of the refrigeration unit 100 as shown in FIG. 2. The shelves 114 include a front portion 126 and a rear portion 128.

Embodiments of the present invention provide sufficient, even lighting across the front of the merchandise, allowing consumers to easily view and access merchandise. Although the lighting units are preferably oriented vertically, the light units may also be oriented horizontally to achieve a similar effect.

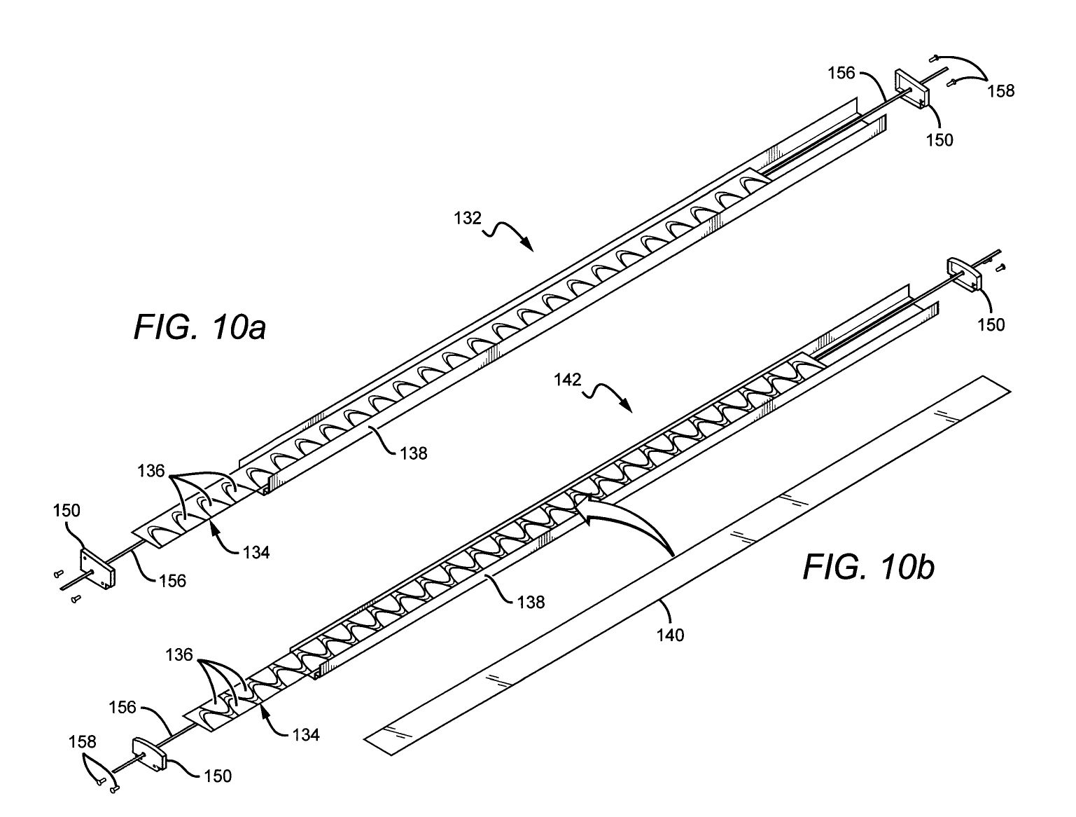

According to embodiments of the present invention, as shown in FIGS. 10a and 10b, the lighting units 132, 142, which are mounted to the vertical supports and mullions 116, 120, 124, comprise a number of light emitting diodes (LEDs) mounted on a printed circuit board (PCB) 134 with reflectors 136 placed over or around them. The LEDs, PCB 134, and reflectors 136 are placed inside a housing 138 with a lens or cover 140 over the open light emitting portion of the housing. As shown in more detail in FIGS. 10a and 10b, this housing can include end caps 150 at each end to close off the housing from the environment while providing openings to pass wiring 156. These end caps 150 may be secured by screws 158, or any other suitable securing means.

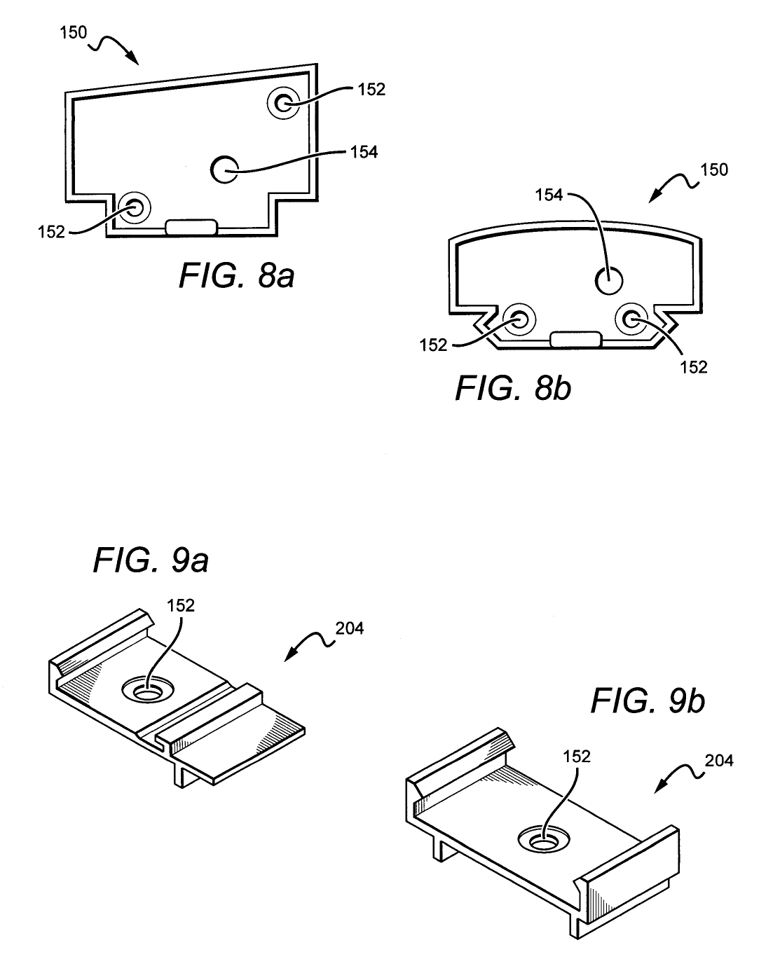

Examples of end caps 150 are shown in FIG. 8a for an end lighting unit 132 and in FIG. 8b for a center lighting unit 142. End caps 150 can include a plurality of screw holes 152 and wire through holes 154, the number of which may be different from those shown in the figures.

The light emitters can be any device that emits light in response to an electrical signal, such as incandescent lights, lasers, laser diodes, fluorescent light or neon lights, with on suitable type of light emitters being light emitting diodes (LEDs). The light emitters can emit different colors of light at varying intensities, with a suitable emitter being a commercially available high luminous flux white LED. A variety of LEDs with different directivity, electrical ratings, thermal resistance, and luminous flux may be used in embodiments of the present invention. Two examples of suitable LEDs include surface mount LEDs, such as the Nichia NS2X123B, and Piranha LEDs, such as the Raijin made by Nichia.

The PCB 134 can be any conventional type made from any conventional material, with an acceptable PCB 134 being a metal core type PCB. Different types of metal core boards can be used such as an aluminum core board, for example metal cores conduct heat from the light elements into the PCB 134 so that the PCB 134 can function as a heat sink. The PCB 134 provides a larger surface that allows the heat to dissipate into the surrounding ambient. This structure can help keep the light emitters cooler, allowing them to operate under a higher current for higher luminous flux. Thermal vias may be added around the light emitters to allow for better, more efficient heat transfer.

Lighting units according to the present invention can also comprise other elements, with one embodiment comprising heat sinks to dissipate heat from the light emitters. Another embodiment may comprise constant current devices that can be mounted on the PCB 134 using conventional methods. This allows each of the units to have substantially the same current driving the light emitters so that each of the lighting units emits substantially the same amount of light. The light emitters and constant current device can be interconnected by conductive traces on the PCB 134 using conventional methods. Without a constant current device, the lighting unit can experience light loss as the power signal passes down the conductors through each of the lighting units. This can ultimately result in a lighting unit exhibiting different brightness across the display case. By driving each of the light emitters in each of the lighting units with the same current, the light emitters along the conductors will have the same brightness. Many different constant current devices can be used, with a suitable device being an LM317M 3-Terminal Adjustable Regulator provided by Texas Instruments, National Semiconductor, and Fairchild Semiconductor.

Lighting units according to embodiments of the present invention can also comprise power modules which allow the power used or consumed by the lighting unit to be adjustable. These power modules can provide a means to adjust the brightness of the lighting units either in discrete steps or continuously.

Other embodiments of the present invention may utilize other means to achieve uniform light dispersion. In various embodiments, the shape of the reflectors and lenses 140 can be modified to accommodate light emitting diodes of different intensities and allow for light uniformity at different display depths.

End lighting units 132 are operatively connected to the interior surface of the left and right vertical supports 116 and 120 within the cavity 102 of the refrigeration unit 100, as shown in FIGS. 2, 3, 4, and 11a. Because these lighting units 132 are shown and described as being in a vertical orientation, the other orientations are described relative to these lighting units 132 in the vertical orientation. Should these lighting units 132 be placed in a different orientation, it is understood that the elements can be adjusted accordingly. Further, the lighting units 132 are also described in an orientation referred to as a front view although the front view of the lighting units 132 is a different orientation than that described for the refrigeration unit 100 as shown in FIGS. 1 and 2.

In one embodiment, end lighting units 132, such as those shown in FIGS. 2, 3, 4, 10a, and 11a, are designed to only emit light to the side of the refrigeration unit where the merchandise is displayed 102. End lighting units 132, therefore, only have emitters and reflectors facing one direction. The reflectors and emitters, individually, can be the same for both end and center lighting units. These end lighting units 132 can be mounted on either the left or right side of a display unit 100 by inverting the end lighting unit 132. Specifically, by rotating the end lighting unit 132 by 180 degrees on both the horizontal axis and the vertical axis. End lighting units 132 can have wiring for power provided on both ends to eliminate the need for unsightly wires when the end lighting unit 132 is used in the inverted position. Center lighting units 142, are designed to illuminate merchandise on both sides of the mullion 124 on which the unit is mounted.

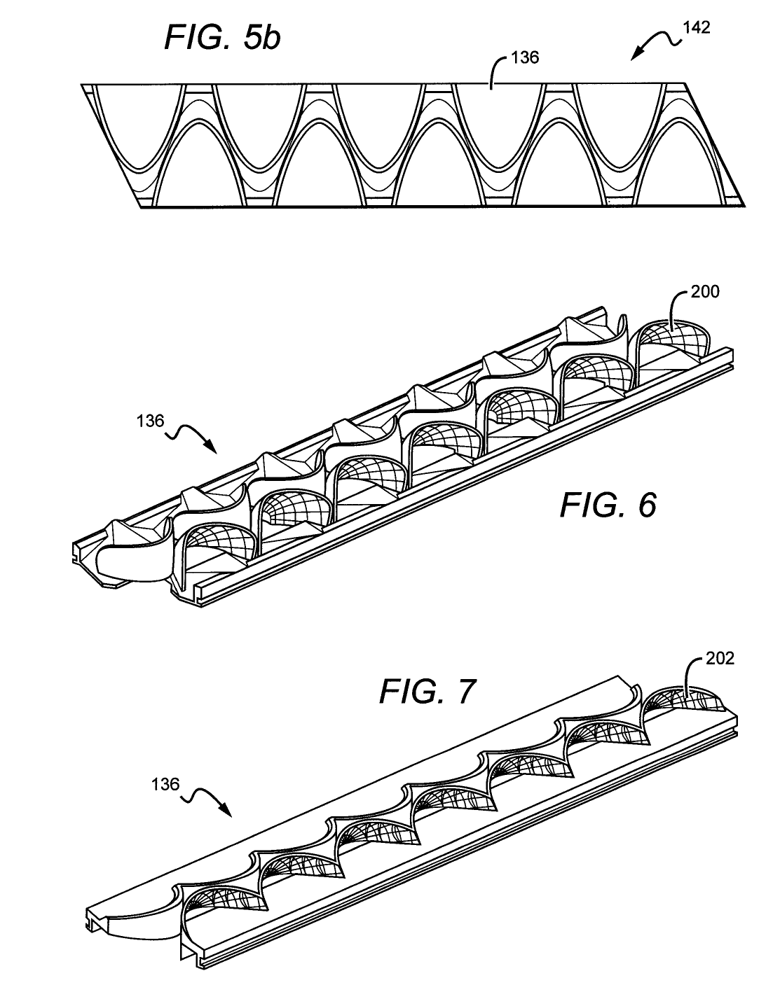

In one embodiment, as shown in FIGS. 2, 3, 5a, 5b, 10b and 11b, the center lighting unit 142 is designed to output light on both sides of the mullion 124. Center lighting units 142, therefore, have emitters and reflectors facing two directions. Center lighting units 142 can have wiring 156 for power provided on both or either end to eliminate the need for unsightly wires when the center lighting unit 142 is used in its inverted position.

In one embodiment, as shown in FIG. 6, the reflector 200 is constructed of a partial parabola with many facets lining the surface of the parabola used to redirect the light emitted from the light emitters. These facets break up the light emitted from the light emitter to spread the light evenly and softly, avoiding the creation of a spot light on the displayed merchandise. These facets and parabola also allow for the light emitted from each emitter to crossover with light from neighboring emitters and avoid dark areas between light emitters. The top of the parabola is left partially open. This allows for the reflectors to have a lower profile and prevents blocking or inefficient redirection of light that would be directly output from the LEDs onto displayed merchandise. The flat surface of the reflector, or portion which is not a partial parabola, is not smooth but rather textured to scatter light reflected off the housing cover or lens 140. This scattering prevents the creation of a bright stripe near the lighting unit caused by light being reflected directly up towards the housing cover or lens 140. The reflectors in this embodiment may all be identical in the series or can include a variety of different reflectors side by side, such as the alternating reflectors shown in FIG. 12 (marked by letters A and B to show alternate placement). A variety of light emitters may be used in this embodiment, one example being a light emitting diode with a 140 degree viewing angle.

In another embodiment, shown in FIG. 7, the reflector 202 is comprised of a several partial parabolic reflectors placed within each other to redirect the light emitted from the light emitters. This series of partial parabolic reflectors mix or break up the light from the emitter to spread it evenly and softly, avoiding the creation of a spot light on the displayed merchandise. The partial parabolic design also allows for more precise redirection of the light to accommodate display cases which have merchandise displayed at a range of distances from the glass door. This more precise redirection of light is possible because each partial parabola may be tuned to redirect a portion of the light as if it were an independent reflector. This series of partial parabolic reflectors also allows for the light from each emitter to crossover with light from neighboring emitters, preventing dark areas between light emitters.

The top of the reflector is left partially open. This allows for the reflectors to have a lower profile and prevents blocking or inefficient redirection of light that would be directly output from the LEDs onto displayed merchandise. Using a reflector comprised of a series of partial parabolic reflectors also allows precise redirection of light without the use of complicated lens structures which increase the profile or height of the lighting unit.

The light emitters can be mounted on the PCB inline with each other. Also, the light emitters can be mounted on the PCB in an offset pattern, rather than inline, allowing the opposite facing reflectors to extend nearly the entire width of the lighting unit. This arrangement provides better control of the emitted light by adding space for reflectors. A variety of light emitters may be used in this embodiment, one example being a light emitting diode with a 150 degree viewing angle.

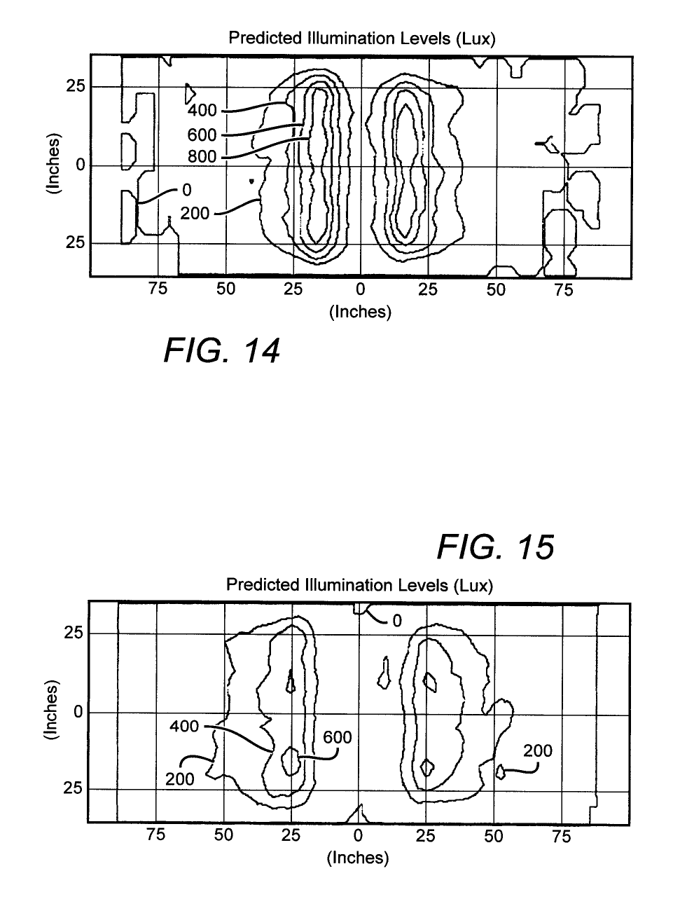

Model illumination plots from embodiments discussed herein are shown in FIGS. 13, 14, and 15. FIG. 13 shows a model illumination plot at a 3⅝″ merchandising plane. FIG. 14 shows a model illumination plot at a 6″ merchandising plane. FIG. 13 shows a model illumination plot at a 10″ merchandising plane. Other reflector configurations can result in illumination plots different from those shown.

The lens 140 over the housing may be any shape or size. In other embodiments, the lens 140 covering the housing of the lighting unit would be as flat as possible to maintain a low profile and would extend at least part way down the side edge or edges of the housing unit to allow for the output of light in the direction of the side edge or edges of the housing unit. Lenses can also be provided in other shapes or designed to actively direct the light from the lighting unit.

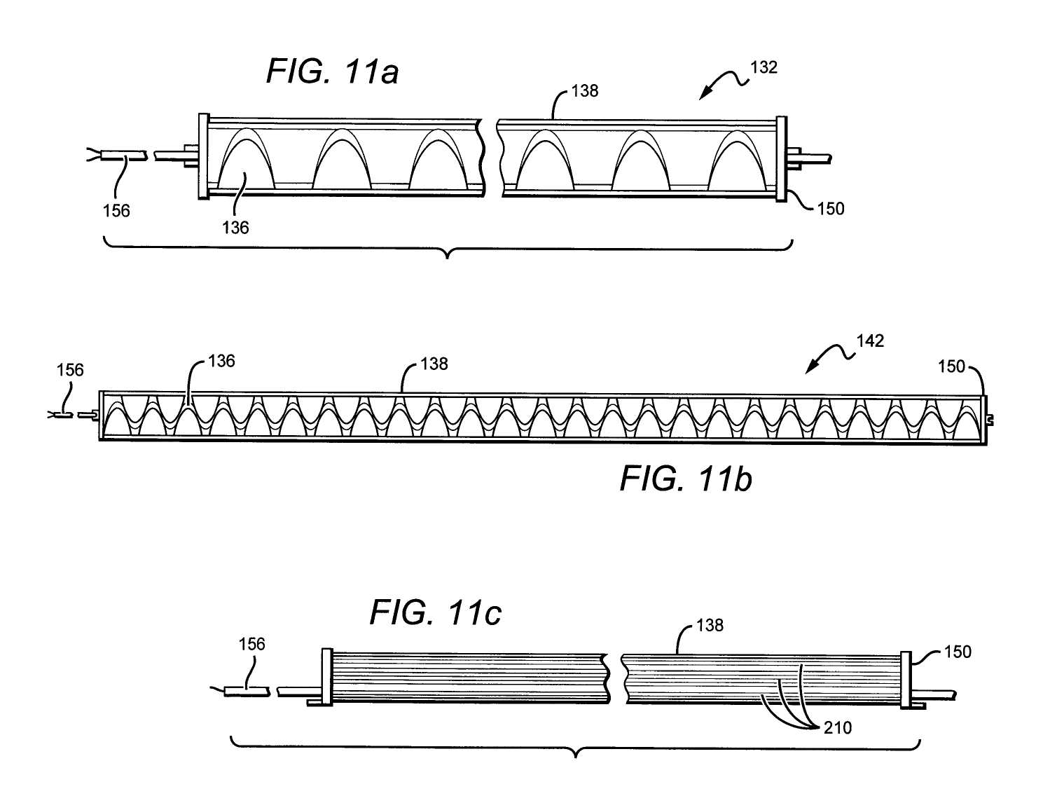

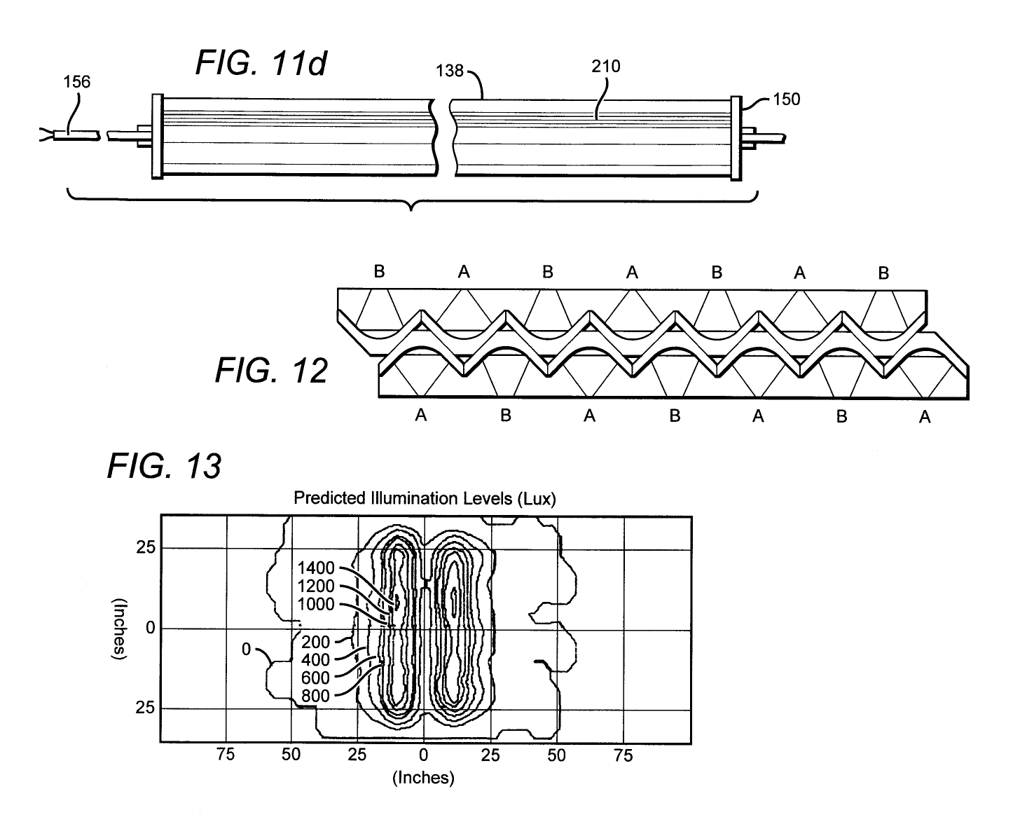

The lighting unit can be attached to the vertical supports 116, 120 or mullions 124 of the refrigeration or display case using a variety of methods including direct mounting of the lighting units to the vertical supports 116, 120 or mullions 124. Direct mounting can be by adhesive strip, screw, nail, bolt, or any other suitable method. In one embodiment the lighting units are mounted to the vertical supports 116, 120 or mullions 124 by clips 204 which are screwed into the vertical supports 116, 120 or mullions 124. As shown in FIGS. 9a and 9b, clips 204 would guide installers by providing the appropriate amount of spacing between the vertical supports 116, 120 or mullions 124 and the lighting unit. These clips 204 can be made of a variety of materials, some examples including steel and polycarbonate. The outside of the lighting unit, or housing, may have a variety of decorative grooves 210 as shown in FIGS. 11c and 11d or grooves that cooperate with the clips 204.

In other embodiments, the lighting unit may be mounted to the ceiling inside of a large refrigerated display case to provide lighting to areas behind shelves where products are stocked. These lighting units have light emitters mounted to a PCB 134 similar to embodiments discussed herein. However the emitters and PCB are placed within the housing at an angle, angled away from the center of the lighting unit. Reflectors may be used over these angled emitters. This angling allows for light to be spread evenly over the room or area being lit by the ceiling mounted lighting unit.

Lighting systems according to the present invention can be arranged in many different ways to allow for uniform lighting of displayed items at different distances from the lighting units or the use of light emitters of different types and outputs in the lighting units. In embodiments described herein, the uniformity of lighting may be controlled for light emitters of different output intensities by adjusting the sizes and parabolas of the reflectors. Refrigeration or display units may have different sizes of merchandise storage areas or glass viewing areas. Refrigeration or display units may have different numbers of doors or viewing areas, different spacing between lighting units and displayed merchandise, and different numbers of supports and mullions for light unit mounting. Also, these supports and mullions can be a variety of widths. It is further understood that different applications of different combinations of reflectors can be utilized to achieve the desired emission characteristics for the lighting system.

Although the present invention has been described in considerable detail with reference to certain preferred configurations thereof, other versions are possible. Lighting units according to the invention can be used for many different applications beyond display cases. The lighting unit can be many different sizes and can be used in many different applications beyond display cases. The PCB can have different numbers of LEDs and can have different electronic components arranged in different ways. The reflectors can be different shapes, spaced differently throughout the housing, and may be placed in the housing unit using a variety of methods, including customizable sizing of reflector strips. This would allow the reflectors to provide different illumination patterns or be supplied separately and then placed within the housing during installation. Therefore, the spirit and scope of the invention should not be limited to embodiments described above.

A number of exemplary figures have been included which have model measurements of embodiments described herein, but embodiments of the present invention are not limited to depictions and measurements in these exemplary figures.

We claim:

1. A lighting unit, comprising:
a housing;
a printed circuit board (PCB) mounted within said housing and having a plurality of light emitting elements on said PCB which emit light when an electrical signal is applied to said light emitters; and
a plurality of reflectors, each of which comprised of an at least one partial parabola which reflects light substantially away from said housing, said plurality of reflectors over said PCB and said light emitters such that each of said light emitters is surrounded by at least one of said plurality of reflectors.

2. The lighting unit of claim 1 wherein said plurality of reflectors are connected.

3. The lighting unit of claim 1 further comprising a mounting mechanism.

4. The lighting unit of claim 3 wherein said mounting mechanism comprises a clip which can be attached to a mounting surface.

5. The lighting unit of claim 4 wherein said housing further comprises grooves which cooperate with said clip.

6. The lighting unit of claim 3 wherein said mounting mechanism comprises an adhesive strip.

7. The lighting unit of claim 1 wherein said partial parabolas further comprise a plurality of facets.

8. The lighting unit of claim 1 wherein said plurality of reflectors guide the light such that light from adjacent light emitters crossover avoiding dark areas between said light emitters on illuminated surfaces.

9. The lighting unit of claim 1 wherein the surface of said plurality of reflectors parallel to said PCB is textured.

10. The lighting unit of claim 1 further comprising an at least one lens over said plurality of reflectors.

11. The lighting unit of claim 10 wherein said lens has a low profile.

12. The lighting unit of claim 1 further comprising a housing cover over said plurality of reflectors.

13. The lighting unit of claim 1 wherein said plurality of reflectors prevent light from said light emitters from being emitted primarily up from said emitters.

14. The lighting unit of claim 1 wherein the structure of said plurality of reflectors alternates between adjacent light emitters.

15. The lighting unit of claim 1 wherein said light emitters are mounted inline on said PCB.

16. The lighting unit of claim 1 wherein said light emitters are mounted staggered from each other on said PCB.

17. The lighting unit of claim 1 wherein each of said plurality of reflectors is comprised of two or more partial parabolic reflectors placed within each other.

18. The lighting unit of claim 17 wherein each of said two or more partial parabolic reflectors redirects a portion of the light to a different area.

19. The lighting unit of claim 3 wherein said lighting unit is mounted vertically in a display case.

20. The lighting unit of claim 3 wherein said lighting unit is mounted horizontally in a display case.

21. The lighting unit of claim 3 wherein said lighting unit is mounted overhead.

22. The lighting unit of claim 21 wherein said PCB is mounted at an angle within said housing.

23. The lighting unit of claim 21 wherein said light emitters are mounted at an angle on said PCB.

24. The lighting unit of claim 1 wherein said unit further comprises a constant current device, which accepts said electrical signal and provides substantially the same current to the light emitters.

25. The lighting unit of claim 1 wherein at least one said PCB in said lighting unit comprises a metal core PCB arranged to conduct heat away from said light emitters.

26. The lighting unit of claim 1 wherein said PCB in said lighting unit comprises alternating layers of polyimide film and copper.

27. The lighting unit of claim 1 wherein said PCB further comprises vias arranged in proximity to said light emitters for heat dissipation.

28. The lighting unit of claim 1 wherein said PCB is capable of conducting and dissipating heat from said light emitters.

29. The lighting unit of claim 1 wherein at least one of said light emitters comprises a light emitting diode.

30. The lighting unit of claim 1 wherein at least one of said light emitters comprises a high luminous flux light emitting diode emitting white light.

31. The lighting unit of claim 1 wherein said housing only partially encloses said unit.

32. The lighting unit of claim 1 wherein said light emitters and reflectors are arranged such that an illuminated surface is lit with even light intensity.

33. The lighting unit of claim 1 wherein the light output from each of said light emitters is partially overlapping with another of said light emitters.

34. A lighting system, comprising:
a plurality of electrically connected lighting units, comprising conductors to provide an electrical signal to each of said units, each of which comprises
a housing;
a printed circuit board (PCB) mounted within said housing and having a plurality of light emitting elements on said PCB which emit light when an electrical signal is applied to said light emitters; and
an at least one reflector over said PCB and said light emitters such that each of said light emitters is surrounded by an at least one partial parabola formed by said reflector, said at least one partial parabola reflecting light substantially away from said housing.

35. The lighting system of claim 34 further comprising a power module which allows the power used or consumed by the lighting unit to be adjustable.

36. The lighting system of claim 34 further comprising a mounting mechanism.

37. The lighting system of claim 36 wherein said mounting mechanism comprises a clip which can be attached to a mounting surface.

38. The lighting system of claim 37 wherein said housing further comprises grooves which cooperate with said clip.

39. The lighting system of claim 36 wherein said mounting mechanism comprises an adhesive strip.

40. The lighting system of claim 34 wherein said partial parabola further comprises a plurality of facets.

41. The lighting system of claim 34 wherein said at least one reflector reflects the light such that light from adjacent light emitters overlap, avoiding dark areas between said light emitters on illuminated surfaces.

42. The lighting system of claim 34 wherein the surface of said at least one reflector parallel to said PCB is textured.

43. The lighting system of claim 34 further comprising an at least one lens over said at least one reflector.

44. The lighting system of claim 43 wherein said lens has a low profile.

45. The lighting system of claim 34 further comprising a housing cover over said at least one reflector.

46. The lighting system of claim 34 wherein said at least one reflector prevents light from said light emitters from being emitted in a direction primarily perpendicular to said PCB.

47. The lighting system of claim 34 wherein the structure of said at least one reflector alternates between adjacent light emitters.

48. The lighting system of claim 34 wherein said light emitters are mounted inline on said PCB.

49. The lighting system of claim 34 wherein said light emitters are mounted staggered from each other on said PCB.

50. The lighting system of claim 34 wherein each of said at least one reflectors is comprised of two or more partial parabolic reflectors placed within each other.

51. The lighting system of claim 50 wherein each of said two or more partial parabolic reflectors redirects a portion of the light to a different area.

52. The lighting system of claim 36 wherein said lighting unit is mounted vertically in a display case.

53. The lighting system of claim 36 wherein said lighting unit is mounted horizontally in a display case.

54. The lighting system of claim 36 wherein said lighting unit is mounted overhead.

55. The lighting system of claim 54 wherein said PCB is mounted at an angle within said housing.

56. The lighting system of claim 54 wherein said light emitters are mounted at an angle on said PCB.

57. The lighting system of claim 34 wherein said unit further comprises a constant current device, which accepts said electrical signal and provides substantially the same current to the light emitters.

58. The lighting system of claim 34 wherein at least one said PCB in said lighting unit comprises a metal core PCB arranged to conduct heat away from said light emitters.

59. The lighting system of claim 34 wherein said PCB in said lighting unit comprises alternating layers of polyimide film and copper.

60. The lighting system of claim 34 wherein said PCB further comprises vias arranged in proximity to said light emitters for heat dissipation.

61. The lighting system of claim 34 wherein said PCB is capable of conducting and dissipating heat from said light emitters.

62. The lighting system of claim 34 wherein at least one of said light emitters comprises a light emitting diode.

63. The lighting system of claim 34 wherein at least one of said light emitters comprises a high luminous flux light emitting diode emitting white light.

64. The lighting system of claim 34 wherein said housing only partially encloses said unit.

65. The lighting system of claim 34 wherein said light emitters and reflectors are arranged such that an illuminated surface is lit with even light intensity.

66. The lighting system of claim 34 wherein the light output from each of said light emitters is partially overlapping with another of said light emitters.

67. The lighting system of claim 34 wherein said units electrically connect to said conductors by soldering.

68. The lighting system of claim 34 wherein said units electrically connect to said conductors by IDC connectors.

69. A display case lighting system, comprising:
a plurality of electrically connected lighting units, comprising conductors to provide an electrical signal to each of said units, each of which comprises
a housing;
a printed circuit board (PCB) mounted within said housing and having a plurality of light emitting elements on said PCB which emit light when an electrical signal is applied to said light emitters;
an at least one reflector over said PCB and said light emitters such that each of said light emitters is surrounded by an at least one partial parabola formed by said reflector, said at least one partial parabola reflecting light substantially away from said housing; and
a mounting mechanism for mounting said lighting units within a display case.

70. The display case lighting system of claim 69 further comprising a power module which allows the power used or consumed by the lighting unit to be adjustable.

71. The display case lighting system of claim 69 wherein said mounting mechanism comprises a clip which can be attached to a mounting surface.

72. The display case lighting system of claim 69 wherein said partial parabola further comprises a plurality of facets.

73. The display case lighting system of claim 69 wherein said at least one reflector reflects the light such that light from adjacent light emitters overlap, avoiding dark areas between said light emitters on an illuminated surfaces within said display case.

74. The display case lighting system of claim 69 wherein the surface of said at least one reflector parallel to said PCB is textured.

75. The display case lighting system of claim 69 further comprising an at least one lens over said at least one reflector.

76. The display case lighting system of claim 69 further comprising a housing cover over said at least one reflector.

77. The display case lighting system of claim 69 wherein said at least one reflector prevents light from said light emitters from being emitted in a direction primarily perpendicular to said PCB.

78. The display case lighting system of claim 69 wherein the structure of said at least one reflector alternates between adjacent light emitters.

79. The display case lighting system of claim 69 wherein said light emitters are mounted inline on said PCB.

80. The display case lighting system of claim 69 wherein said light emitters are mounted staggered from each other on said PCB.

81. The display case lighting system of claim 69 wherein each of said at least one reflectors is comprised of two or more partial parabolic reflectors placed within each other.

82. The display case lighting system of claim 81 wherein each of said two or more partial parabolic reflectors redirects a portion of the light to a different area.

83. The display case lighting system of claim 69 wherein said lighting unit is mounted vertically in a display case.

84. The display case lighting system of claim 69 wherein said lighting unit is mounted horizontally in a display case.

85. The display case lighting system of claim 69 wherein said unit further comprises a constant current device, which accepts said electrical signal and provides substantially the same current to the light emitters.

86. The display case lighting system of claim 69 wherein at least one of said light emitters comprises a light emitting diode.

87. The display case lighting system of claim 69 wherein said housing only partially encloses said unit.

88. The display case lighting system of claim 69 wherein said light emitters and reflectors are arranged such that said display case is lit with even light intensity.

89. The display case lighting system of claim 69 wherein the light output from each of said light emitters is partially overlapping with another of said light emitters.

90. A method of lighting the interior of a display case, comprising:
providing a housing;
mounting a printed circuit board (PCB) within said housing and having a plurality of light emitting elements on said PCB which emit light when an electrical signal is applied to said light emitters;
providing an at least one reflector over said PCB and said light emitters such that each of said light emitters is surrounded by an at least one partial parabola formed by said reflector, said at least one partial parabola reflecting light substantially away from said housing;
mounting said lighting units within a display case;
redirecting light emitted from said light emitters with said at least one reflector such that said at least one partial parabola reflects evenly dispersed light in said display case and emitted light from each of said light emitters partially overlapping the emitted light of at least one other light emitter.

91. The method of claim 90 further comprising controlling the power consumed by said lighting unit by using a power module.

92. The method of claim 90 further comprising using a current control device to provide uniform light output from each of said light emitters.

93. The method of claim 90 wherein said partial parabola further comprises a plurality of facets.

94. The method of claim 90 wherein the surface of said at least one reflector parallel to said PCB is textured.

95. The method of claim 90 further comprising providing an at least one lens over said at least one reflector.

96. The method of claim 90 wherein said at least one reflector prevents light from said light emitters from being emitted in a direction primarily perpendicular to said PCB.

97. The method of claim 90 wherein each of said partial parabolic reflectors redirects a portion of the light to a different area.

98. The method of claim 90 wherein said lighting unit is mounted vertically in a display case.

99. The method of claim 90 wherein said lighting unit is mounted horizontally in a display case.

100. The display case lighting system of claim 69 wherein at least one of said light emitters comprises a light emitting diode.
